(19) United States
(12) Patent Application Publication
(10) Pub. No.: US 2026/0101712 A1
(43) Pub. Date: Apr. 9, 2026

(54) SEMICONDUCTOR MANUFACTURING APPARATUS

(71) Applicant: Samsung Electronics Co., Ltd., Suwon-si (KR)

(72) Inventors: Jaeho Hong, Suwon-si (KR); SOONWOOK KIM, Suwon-si (KR); Sangjun Park, Suwon-si (KR); TAE-HOI PARK, Suwon-si (KR); SANG-HO YUN, Suwon-si (KR)

(21) Appl. No.: 19/277,319

(22) Filed: Jul. 22, 2025

(30) Foreign Application Priority Data
Oct. 7, 2024 (KR) 10-2024-0136094

(51) Int. Cl. H01L 21/68; G01B 11/27; H01L 21/67

(52) U.S. Cl. CPC H10P 72/53; G01B 11/272; H10P 72/0438

(57) ABSTRACT

A semiconductor manufacturing apparatus includes a first chuck that has a first surface and a second surface opposite each other and receives a first substrate on the first surface, a second chuck that has a third surface and a fourth surface opposite each other and receives a second substrate on the third surface, a first imaging device connected to one side of the first chuck, and a second imaging device connected to one side of the second chuck. Each of the first imaging device and the second imaging device includes a light blocking part, and the light blocking part blocks a first portion of reflected light reflected from a first alignment key on the first substrate or a second alignment key on the second substrate.

### CROSS-REFERENCE TO RELATED APPLICATIONS

This application claims priority under 35 U.S.C. § 119 to Korean Patent Application No. 10-2024-0136094 filed on Oct. 7, 2024, in the Korean Intellectual Property Office, the disclosures of which are incorporated by reference herein in their entireties.

### BACKGROUND

Embodiments of the present disclosure described herein relate to a semiconductor manufacturing apparatus.

Semiconductor devices may be manufactured using various semiconductor manufacturing processes. As one of the semiconductor manufacturing processes, a semiconductor substrate bonding process may be performed. The bonding process may be a process of physically and/or chemically bonding two or more semiconductor substrates to each other to form a single structure. With the high integration of semiconductor devices, refinement of the bonding process is desirable. For the refinement of the bonding process, more precise alignment accuracy of the semiconductor substrates is desirable.

### SUMMARY

Embodiments of the present disclosure provide a semiconductor manufacturing apparatus having improved semiconductor substrate alignment accuracy.

According to an embodiment, a semiconductor manufacturing apparatus includes a first chuck having a first surface and a second surface opposite each other, the first chuck being configured to receive a first substrate on the first surface; a second chuck having a third surface and a fourth surface opposite each other, the second chuck being configured to receive a second substrate on the third surface; a first imaging device connected to one side of the first chuck; and a second imaging device connected to one side of the second chuck, wherein each of the first imaging device and the second imaging device includes a light blocking part, and wherein, for each of the first imaging device and the second imaging device, the light blocking part is configured to block a first portion of reflected light reflected from a first alignment key on the first substrate or a second alignment key on the second substrate.

According to an embodiment, a semiconductor manufacturing apparatus includes a first chuck having a first surface and a second surface opposite each other, the first chuck being configured to receive a first substrate on the first surface; a second chuck having a third surface and a fourth surface opposite each other, the second chuck being configured to receive a second substrate on the third surface; a first imaging device connected to one side of the first chuck; and a second imaging device connected to one side of the second chuck, wherein each of the first imaging device and the second imaging device includes a light blocking part, wherein reflected light reflected from a first alignment key on the first substrate and a second alignment key on the second substrate includes a first portion having a first intensity and a second portion having a second intensity lower than the first intensity, and wherein, for each of the first imaging device and the second imaging device, the light blocking part is configured to block the first portion of the reflected light.

According to an embodiment, a semiconductor manufacturing apparatus includes a first chuck having a first surface and a second surface opposite each other, the first chuck being configured to receive a first substrate on the first surface; a second chuck having a third surface and a fourth surface opposite each other, the second chuck being configured to receive a second substrate on the third surface; a first imaging device connected to one side of the first chuck; and a second imaging device connected to one side of the second chuck, wherein each of the first imaging device and the second imaging device includes: a light source configured to emit light; a light blocking part configured to block a first portion of reflected light reflected from a first alignment key on the first substrate or a second alignment key on the second substrate; an objective lens configured to transmit the light emitted from the light source; a photo detector configured to detect a second portion of the reflected light, and a light guide configured to guide the second portion of the reflected light to the photo detector, and wherein, for each of the first imaging device and the second imaging device: the light source is provided between the objective lens and the light blocking part, the light blocking part is provided between the light source and the light guide, and the reflected light includes a plurality of order lights formed by diffraction and/or interference, and the first portion of the reflected light blocked by the light blocking part is zero order light among the plurality of order lights.

According to an embodiment, a method of manufacturing a semiconductor device includes providing a first substrate on a first chuck, the first substrate having a first alignment key formed thereon; providing a second substrate on a second chuck, the second substrate having a second alignment key formed thereon, the second chuck being positioned above the first chuck such that the first substrate and the second substrate face each other; using a first imaging device positioned next to the first chuck, capturing a first image of the second alignment key; during the capturing of the first image, using a first baffle, blocking zero order light reflected by the second alignment key; using a second imaging device positioned next to the second chuck, capturing a second image of the first alignment key; during the capturing of the second image, using a second baffle, blocking zero order light reflected by the first alignment key; and using the first image and the second image, aligning the first substrate with the second substrate and bonding the first substrate to the second substrate.

### BRIEF DESCRIPTION OF THE FIGURES

The above and other objects and features of the present disclosure will become apparent by describing in detail embodiments thereof with reference to the accompanying drawings.

FIG. 1 is a sectional view of a semiconductor manufacturing apparatus according to an embodiment of the present disclosure.

FIG. 2 is a sectional view illustrating a first imaging device according to an embodiment of the present disclosure.

FIG. 3 is a plan view illustrating a first alignment key configured in the semiconductor manufacturing apparatus according to an embodiment of the present disclosure.

FIGS. 4A and 4B are plan views in which a light blocking part is illustrated on the first alignment key according to an embodiment of the present disclosure.

FIGS. 5A and 5B are sectional views illustrating a process in which light emitted from the first image device or the second imaging device is reflected by the first alignment key or the second alignment key and blocked by the light blocking part in the semiconductor manufacturing apparatus according to an embodiment of the present disclosure.

FIGS. 6A and 6B are signal graphs recognized by a photo detector included in the semiconductor manufacturing apparatus according to an embodiment of the present disclosure.

FIGS. 7A to 7C are sectional views illustrating an operating method of the semiconductor manufacturing apparatus according to an embodiment of the present disclosure.

FIG. 8 is a view illustrating a simulation result obtained by measuring an alignment error when substrates are bonded using the semiconductor manufacturing apparatus according to an embodiment of the present disclosure.

FIG. 9 shows a method of manufacturing a semiconductor device according to an embodiment of the present disclosure.

### DETAILED DESCRIPTION

Hereinafter, embodiments of the present disclosure will be described in more detail with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

An item, layer, or portion of an item or layer described as “extending” or as extending “lengthwise” in a particular direction has a length in the particular direction and a width perpendicular to that direction, where the length is greater than the width.

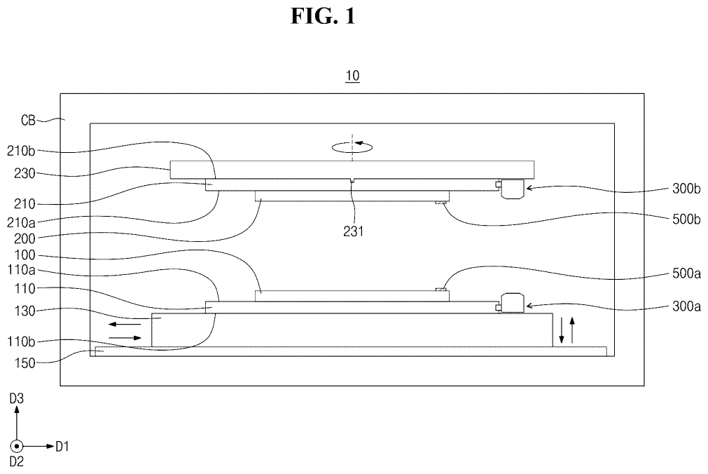

FIG. 1 is a sectional view of a semiconductor manufacturing apparatus according to an embodiment of the present disclosure.

Referring to FIG. 1, the semiconductor manufacturing apparatus 10 is equipment that performs various processes necessary to manufacture a high-performance semiconductor chip on a semiconductor substrate. The semiconductor manufacturing apparatus 10 may be, for example, an etching apparatus, a deposition apparatus, an ion implantation apparatus, an oxidation apparatus, a chemical mechanical polishing apparatus, an inspection and measurement apparatus, or a substrate bonding apparatus.

The semiconductor manufacturing apparatus 10 according to an embodiment of the present disclosure may be a substrate bonding apparatus for bonding two substrates. The substrate bonding apparatus is equipment used to perform a bonding process of precisely aligning substrates and physically and/or chemically bonding the substrates in a semiconductor manufacturing process. Here, the substrates may include a silicon on insulator (SOI) substrate, a metal substrate, a glass substrate, or a plastic substrate as well as a semiconductor substrate made of a semiconductor material. The semiconductor substrate may be, for example, a silicon substrate, a germanium substrate, or a silicon-germanium substrate.

The semiconductor manufacturing apparatus 10 according to an embodiment of the present disclosure may include a chamber CB, a first chuck 110, a first stage 130, a first imaging device 300a, a second chuck 210, a second stage 230, and a second imaging device 300b.

The chamber CB may provide a process space of the semiconductor manufacturing apparatus 10. A semiconductor manufacturing process using the semiconductor manufacturing apparatus 10 may be performed in the process space. The process space may be separated from an outer space by the chamber CB.

The semiconductor manufacturing process using the semiconductor manufacturing apparatus 10 may be performed in the process space of the chamber CB. For example, the semiconductor manufacturing apparatus 10 may perform a substrate bonding process in the chamber CB. The chamber CB may have a cylindrical shape. However, this is illustrative, and the chamber CB may be implemented in various shapes.

The chamber CB may accommodate the first chuck 110 and the second chuck 210. The first chuck 110 may have a first surface 110a and a second surface 110b opposite each other. A first substrate 100, which is an object to be bonded, may be received on the first chuck 110. The first substrate 100 may be received on the first surface 110a of the first chuck 110. Here, the first substrate 100 may have a circular plate shape. However, this is illustrative, and the first substrate 100 having various shapes may be received on the first chuck 110.

The first chuck 110 may safely fix the position of the first substrate 100 such that the first substrate 100 is not shaken. The first chuck 110 may fix or support the first substrate 100 using vacuum pressure, electrostatic force, and/or external force according to Bernoulli's law. That is, the first chuck 110 may allow the first substrate 100 to be stably maintained even under various physical and/or chemical influences that are likely to occur during the semiconductor manufacturing process. The first chuck 110 may have a circular plate shape. When compared to the first substrate 100, the first surface 110a of the first chuck 110 may have an area large enough to receive the first substrate 100. In an embodiment, the first chuck 110 may include a plurality of vacuum grooves and may be a vacuum chuck that attracts the first substrate 100 using a vacuum. However, without being limited thereto, the first chuck 110 may include various types of chucks capable of seating the first substrate 100, for example, an electrostatic chuck, a mechanical chuck, or a magnetic chuck.

In an embodiment, the first chuck 110 may further include an external force generator that generates an attraction force for the first substrate 100. The external force generator may generate an attraction force in the plurality of vacuum grooves. In an embodiment, the external force generator may be a vacuum pump.

The first stage 130 may be provided on the second surface 110b of the first chuck 110. The first stage 130 may fix the position of the first chuck 110. The first stage 130 may have a rectangular plate shape. When compared to the second surface 110b of the first chuck 110, the first stage 130 may have an area large enough to fix the position of the first chuck 110.

The first stage 130 may move in a first direction D1 parallel to the second surface 110b of the first chuck 110, a second direction D2 parallel to the second surface 110b and crossing the first direction D1, and a third direction D3 perpendicular to the first direction D1 and the second direction D2. Accordingly, the first stage 130 may align the first substrate 100 by moving the first chuck 110 configured to fix the first substrate 100.

In an embodiment, various actuators may be connected to the first stage 130. The actuators may serve to move the first stage 130. That is, the first stage 130 may be moved through the actuators. The actuators may control both a horizontal movement of the first stage 130 in the first direction D1 and the second direction D2 and a vertical movement of the first stage 130 in the third direction D3.

The actuators may include, for example, a linear motor that enables a high-speed movement without friction, a piezoelectric actuator that enables a precise movement in units of nanometers (nm), and/or a ball screw capable of controlling a precise movement at low speed.

In an embodiment, a rail 150 may be provided on the lower surface of the first stage 130. The rail 150 may assist the movement of the first stage 130 by providing a path along which the first stage 130 is capable of smoothly and accurately moving. More specifically, the rail 150 may be provided in the shape of an “H” in a planar view (e.g., in a plan view such that the semiconductor manufacturing apparatus 10 is viewed along the third direction D3, which may be a vertical direction), and the first stage 130 may move along the H-shaped path on the rail 150. Accordingly, the rail 150 may provide a horizontal movement path of the first stage 130 in the first direction D1 and the second direction D2. However, the shape and structure of the rail 150 are not limited thereto, and the rail 150 may have various shapes and structures capable of providing a movement path of the first stage 130. The rail 150 may be, for example, a V-shaped rail provided in the shape of a “V” in a sectional view.

The second chuck 210 may be provided over the first chuck 110 to face the first surface 110a of the first chuck 110. The second chuck 210 may have a third surface 210a and a fourth surface 210b opposite each other. The second chuck 210 may be configured to receive a second substrate 200. The second substrate 200 may be an object to be bonded that is received on the third surface 210a of the second chuck 210. Here, the second substrate 200 may be a substrate to be bonded with the first substrate 100 and may be, for example, a semiconductor substrate or an SOI substrate. In an embodiment, the second substrate 200 may have a circular plate shape. However, this is illustrative, and the second substrate 200 having various shapes may be received on the second chuck 210.

The second chuck 210 may serve to safely fix the position of the second substrate 200 such that the second substrate 200 is not shaken. The second chuck 210 may fix or support the second substrate 200 using vacuum pressure, electrostatic force, or external force according to Bernoulli's law. That is, the second chuck 210 may allow the second substrate 200 to be stably maintained even under various physical and/or chemical influences that are likely to occur during the semiconductor manufacturing process. The second chuck 210 may have a circular plate shape. When compared to the second substrate 200, the third surface 210a of the second chuck 210 may have an area large enough to receive the second substrate 200. The second chuck 210 may be a vacuum chuck that attracts the second substrate 200 using vacuum. However, without being limited thereto, the second chuck 210 may include various types of chucks capable of attracting the second substrate 200, for example, an electrostatic chuck, a mechanical chuck, or a magnetic chuck. The shape and structure of the second chuck 210 may be the same as or similar to the shape and structure of the first chuck 110.

The second stage 230 may be provided on the fourth surface 210b of the second chuck 210. The second stage 230 may fix the position of the second chuck 210. The second stage 230 may have a circular plate shape. However, without being limited thereto, the second stage 230 may have a rectangular plate shape. When compared to the fourth surface 210b of the second chuck 210, the second stage 230 may have an area large enough to fix the second chuck 210. In an embodiment, the second stage 230 may have a shape similar to the shape of the second chuck 210.

The second stage 230 may be disposed to face the first stage 130 in a plane parallel to the plane that forms the first direction D1 and the second direction D2. Accordingly, the second stage 230 may be spaced apart from the first stage 130 in the third direction D3 and may be provided over the first stage 130.

In an embodiment, the second stage 230 may include a rotating part 231. The rotating part 231 may be a part that protrudes from the center of the lower surface of the second stage 230 in the direction opposite to the third direction D3. The rotating part 231 may rotate about a rotational axis parallel to the third direction D3. The rotational axis of the rotating part 231 may be set at the center of the rotating part 231. Accordingly, the second stage 230 may rotate about the rotational axis that is set at the center of the rotating part 231 so as to be parallel to the third direction D3. That is, the second stage 230 may be a rotary stage. The second stage 230 may rotate the second chuck 210 through the rotating part 231 and may rotate and align the second substrate 200 accordingly.

In an embodiment, a separate controller (not illustrated) may be connected with the first stage 130, the second stage 230, and the rail 150. The controller may control the actuator to move the first stage 130 in the first direction D1, the second direction D2, and/or the third direction D3 and rotate the second stage 230 about the rotational axis that is set at the center of the rotating part 231 so as to be parallel to the third direction D3. The controller may be implemented in the form of hardware, firmware, or software, or in a combination thereof. The controller may be, for example, a computing device such as a workstation computer, a desktop computer, a laptop computer, or a tablet computer. In addition, the controller may include a memory device such as read only memory (ROM) or random access memory (RAM) and a processor configured to perform a certain operation and algorithm, for example, a microprocessor, a central processing unit (CPU), or a graphics processing unit (GPU). In an embodiment, the controller may include a receiver and a transmitter for receiving and transmitting electrical signals.

In an embodiment, the first substrate 100 received on the first chuck 110 may include a first alignment key 500a, and the second substrate 200 received on the second chuck 210 may include a second alignment key 500b. The first alignment key 500a and the second alignment key 500b may be keys used to accurately align the first substrate 100 and the second substrate 200 with each other, and may be provided on specific portions of the first substrate 100 and the second substrate 200, respectively. The first alignment key 500a and the second alignment key 500b may include metal, plastic, or ceramic.

In an embodiment, the first substrate 100 may include a plurality of first alignment keys 500a, and the second substrate 200 may include a plurality of second alignment keys 500b. In addition, as illustrated in FIG. 1, the first alignment key 500a and the second alignment key 500b may be located on lateral portions of surfaces of the first substrate 100 and the second substrate 200 that face each other. For example, the first alignment key 500a may be located at or near an edge of an upper horizontal surface of the first substrate 100, and the second alignment key 500b may be located at or near an edge of a lower horizontal surface of the second substrate 200. However, the present disclosure is not limited thereto. The first alignment key 500a and the second alignment key 500b may be located on the central portions of the surfaces of the first substrate 100 and the second substrate 200 that face each other. The first alignment key 500a and the second alignment key 500b may be positioned to facilitate proper alignment between the first substrate 100 and the second substrate 200.

In an embodiment, the first alignment key 500a and the second alignment key 500b may have substantially the same size and shape.

The first imaging device 300a may be provided on one side of the first chuck 110. For example, the first imaging device 300a may be provided to one side of the first chuck 110 such that at least a portion of the first imaging device 300a and at least a portion of the first chuck 110 are positioned at the same vertical level. The first imaging device 300a may be connected to the one side of the first chuck 110 through a separate connecting part (e.g., an adhesive, screw, bolt, or other hardware fastener). Here, the term “connect” means a physical connection. The first imaging device 300a may take (e.g., capture) an image of alignment patterns of the second alignment key 500b by applying light in the third direction D3 and may obtain an alignment coordinate value of the second alignment key 500b depending on the image taken of the alignment patterns.

The second imaging device 300b may be provided on one side of the second chuck 210. For example, the second imaging device 300b may be provided to one side of the second chuck 210 such that at least a portion of the second imaging device 300b and at least a portion of the second chuck 210 are positioned at the same vertical level. The second imaging device 300b may be connected to the one side of the second chuck 210 through a separate connecting part (e.g., an adhesive, screw, bolt, or other hardware fastener). Here, the one side of the second chuck 210 may be opposite the one side of the first chuck 110. The second imaging device 300b may take an image of alignment patterns of the first alignment key 500a by applying light in the direction opposite to the third direction D3 and may obtain an alignment coordinate value of the first alignment key 500a depending on the image taken of the alignment patterns.

In an embodiment, each of the first imaging device 300a and the second imaging device 300b may be and/or function as a camera of the semiconductor manufacturing apparatus 10. More specifically, to derive a position alignment value for substrate bonding, each of the first imaging device 300a and the second imaging device 300b may apply light to the corresponding alignment key provided on the substrate, may receive and/or recognize a reflected light signal reflected from the alignment key, and may convert the reflected light signal into a digital signal. The first imaging device 300a and the second imaging device 300b may be symmetrically disposed based on the first surface 110a of the first chuck 110 and the third surface 210a of the second chuck 210 that are opposite each other. More specifically, each of the first imaging device 300a and the second imaging device 300b may have one end (e.g., a first end). The one end of the first imaging device 300a may face upward, and the one end of the second imaging device 300b may face downward. Here, the one end of the first imaging device 300a may be a top of the first imaging device 300a, and the one end of the second imaging device 300b may be a bottom of the second imaging device 300b. In addition, the first imaging device 300a and the second imaging device 300b may have substantially the same structure and shape. However, without being limited thereto, the first imaging device 300a and the second imaging device 300b may have different external appearances.

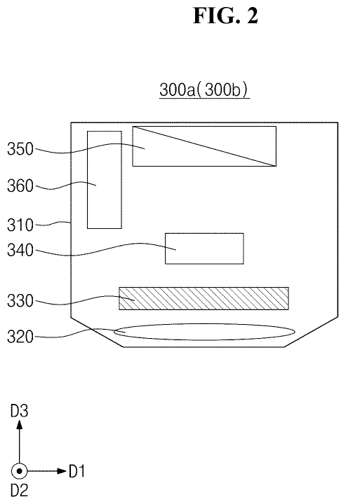

FIG. 2 is a sectional view illustrating the first imaging device included in the semiconductor manufacturing apparatus according to an embodiment of the present disclosure. In an embodiment, the first imaging device 300a and the second image device 300b may be provided in substantially the same structure. Hereinafter, for convenience of description, the first imaging device 300a is illustrated as an example.

Referring to FIG. 2, each of the first imaging device 300a and the second imaging device 300b may include a housing 310, an objective lens 320, a light source 330, a light blocking part 340, a light guide 350, and a photo detector 360.

The housing 310 may be an outer casing that accommodates the components of each of the first imaging device 300a and the second imaging device 300b. That is, the objective lens 320, the light source 330, the light blocking part 340, the light guide 350, and the photo detector 360 may be provided in the housing 310. As illustrated in FIG. 2, the housing 310 may have a hexagonal cross-section and may have a cylindrical shape having a decreasing cross-sectional area toward the bottom (e.g., toward the light-emitting and light-receiving side of the imaging device). However, the shape of the housing 310 is not limited thereto, and the housing 310 having various shapes suitable for performing the function of a camera may be employed.

The light source 330 may be provided in the housing 310. The light source 330 may be configured to output light required for measuring an alignment error of the first substrate 100 or the second substrate 200. More specifically, the light source 330 of the first imaging device 300a may be configured to apply light to the second substrate 200, and the light source 330 of the second imaging device 300b may be configured to apply light to the first substrate 100.

The light source 330 may provide light having various wavelengths. The wavelength of the light emitted from the light source 330 may vary depending on the characteristics of the first substrate 100 and the second substrate 200. More specifically, the wavelength range of the light emitted from the light source 330 may vary depending on an object being measured and may include a visible wavelength range (about 400 nm to about 700 nm), an ultraviolet wavelength range (about 100 nm to about 400 nm), and/or a near infrared wavelength range (about 700 nm to about 2500 nm). In addition, the light source 330 may output extreme ultraviolet (EUV) light corresponding to several tens of nm. In an embodiment, the light source 330 may output white light and/or red light. The light source 330 may be, for example, one or more lasers, one or more light-emitting diodes (LEDs), a combination thereof, and the like.

The objective lens 320 may be provided in the lower portion of the housing 310. That is, the objective lens 320 may be provided in the direction in which the light is emitted and applied from the light source 330. The objective lens 320 may transmit the light emitted from the light source 330. The objective lens 320 may convert the light output from the light source 330 and reflected light reflected from the outside into parallel light parallel to the third direction D3 (e.g., collimated light). The objective lens 320 may be, for example, a spherical lens or an aspheric lens for minimizing aberration. However, without being limited thereto, various types of lenses may be employed as the objective lens 320.

The light blocking part 340 may be provided between the light source 330 and the light guide 350. The light blocking part 340 may block a portion of reflected light reflected from a surface of a specific object by which the light output by the light source 330 is reflected. The light blocking part 340 may block, for example, zero order light among a plurality of order lights formed by diffraction or interference of the reflected light. The light blocking part 340 may be, for example, a baffle, a plate, a wall, a screen, or the like.

In more detail, when light output from a light source is reflected by a surface of a specific object including a plurality of protruding portions, spherical waves that together generate a new wavefront are generated from surfaces between the protruding portions according to Huygens' principle, and the spherical waves are combined to form a plurality of new reflected lights. The reflected lights cause an interference phenomenon in an overlapping portion in space to form an interference pattern. When the interference pattern is represented on a wave graph, portions corresponding to constructive interference are illustrated as local maximum values, and portions corresponding to destructive interference are illustrated as local minimum values. That is, the wave graph appears in the form of a symmetrical sine function in which the local maximum values and the local minimum values alternately oscillate. Lights corresponding to the local maximum values or the local minimum values appearing on the graph are called order lights. The order light corresponding to the first largest maximum value among the local maximum values is called zero order light, the order light corresponding to the second largest maximum value is called first order light, and the order light corresponding to the third largest maximum value is called third order light. The zero order light is order light that travels straight perpendicularly to a reflective surface, and as the order of order light increases, the angle of reflection increases. The zero order light blocked by the light blocking part 340 according to an embodiment of the present disclosure may be light having the highest intensity that travels straight perpendicularly to the first imaging device 300a or the second imaging device 300b by diffraction and/or interference of the light after the light output from the light source 330 is reflected by the first alignment key 500a or the second alignment key 500b.

The light blocking part 340 may include, but is not limited to, metallic materials having a high light blocking rate, organic materials having an opaque property, and/or black carbon (C) having a high absorption rate. The light blocking part 340 may include, for example, a material capable of blocking light or selectively transmitting light. In an embodiment, the light blocking part 340 may be a spot mirror, but is not limited thereto. For example, the light blocking part 340 may be provided in the form of a light blocking film, a light blocking grid or blind (grating), or a block structure.

The light guide 350 may be disposed over the light blocking part 340. The light guide 350 may guide other order lights not blocked by the light blocking part 340 among the plurality of order lights of the reflected light to the photo detector 360 through refraction and/or reflection. In an embodiment, the light guide 350 may be a prism. The light guide 350 may be, for example, a triangular prism, a penta prism, or an amici prism. The light guide 350 may include a transparent and homogeneous material. The light guide 350 may include, for example, glass, polycarbonate, polymethyl methacrylate (PMMA), quartz, or acrylic.

The photo detector 360 may be provided on one side of the light guide 350. The photo detector 360 may detect the other order lights of the reflected light guided by the light guide 350. The photo detector 360 may convert an intensity signal of light, which is an analog signal of light, into a digital signal. More specifically, the photo detector 360 may recognize a light signal, may convert the light signal into a digital signal, and may extract an alignment error, a deformation state, and/or alignment coordinate values of the first substrate 100 and the second substrate 200. In an embodiment, the photo detector 360 may include a charge-coupled device (CCD), a photo-multiplier tube (PMT), or a CMOS sensor.

In an embodiment, the semiconductor manufacturing apparatus 10 may include a separate error alarm. When an alignment error occurs in the substrate bonding process and deviates from a set range, the error alarm may detect the deviation and may send out an alert. The error alarm may be provided in each of the first image device 300a and the second imaging device 300b. However, the arrangement of the error alarm is not limited thereto. For example, the error alarm may be provided outside the first image device 300a and the second imaging device 300b and may be connected to the first image device 300a and the second imaging device 300b through separate wiring. Alternatively, the error alarm may be provided in a safety monitoring device that is installed separately from the semiconductor manufacturing apparatus 10 and that monitors the entire process line.

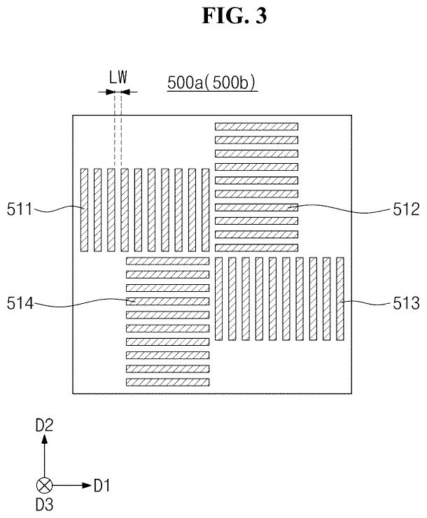

FIG. 3 is a plan view illustrating the first alignment key configured in the semiconductor manufacturing apparatus according to an embodiment of the present disclosure. In an embodiment, the first alignment key 500a and the second alignment key 500b may have substantially the same structure. Hereinafter, for convenience of description, the first alignment key 500a is illustrated as an example.

Referring to FIG. 3, each of the first alignment key 500a and the second alignment key 500b may include first alignment patterns 511, second alignment patterns 512, third alignment patterns 513, and fourth alignment patterns 514. The first alignment patterns 511, the second alignment patterns 512, the third alignment patterns 513, and the fourth alignment patterns 514 may constitute a first alignment pattern group, a second alignment pattern group, a third alignment pattern group, and a fourth alignment pattern group, respectively.

More specifically, the first alignment patterns 511 may be arranged in the first direction D1 and may have bar shapes extending in the second direction D2. The second alignment patterns 512 may be arranged in the second direction D2 and may have bar shapes extending in the first direction D1. The third alignment patterns 513 may be arranged in the first direction D1 and may have bar shapes extending in the second direction D2. The fourth alignment patterns 514 may be arranged in the second direction D2 and may have bar shapes extending in the first direction D1. In addition, the first alignment pattern group, the second alignment pattern group, the third alignment pattern group, and the fourth alignment pattern group may be arranged in the clockwise direction. Accordingly, each of the first alignment key 500a and the second alignment key 500b may have a pinwheel shape in a planar view.

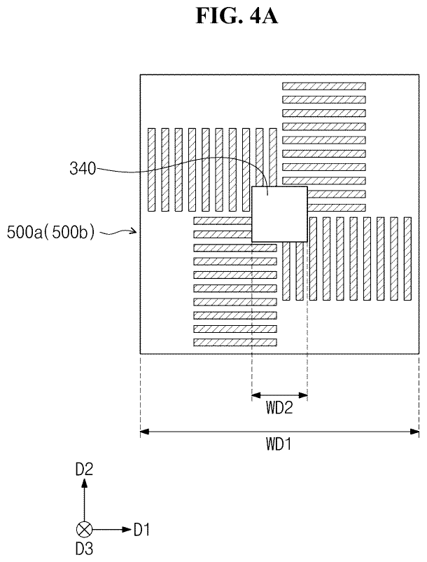

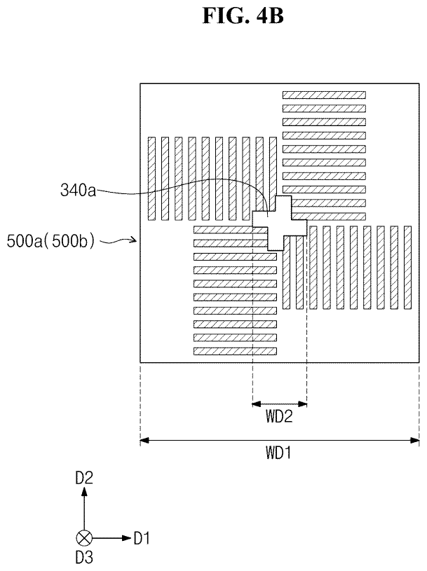

FIGS. 4A and 4B are plan views in which the light blocking part included in the semiconductor manufacturing apparatus is illustrated on the first alignment key according to an embodiment of the present disclosure. In an embodiment, the first alignment key 500a and the second alignment key 500b may be provided in substantially the same structure. Hereinafter, for convenience of description, the first alignment key 500a is illustrated as an example.

Referring to FIGS. 4A and 4B, the size of each of the light blocking parts 340 and 340a may be smaller than the size of each of the first alignment key 500a and the second alignment key 500b. For example, when viewed in plan view, the area (e.g., surface area) of each of the light blocking parts 340 and 340a may be smaller than the area (e.g., surface area) of each of the first alignment key 500a and the second alignment key 500b.

In an embodiment, the light blocking part 340 may have various shapes. For example, as illustrated in FIG. 4A, the light blocking part 340 may have a square shape. However, without being limited thereto, as illustrated in FIG. 4B, the light blocking part 340a may have a pinwheel shape in a planar view. In addition, blades of the pinwheel-shaped light blocking part 340a may overlap the first alignment patterns 511, the second alignment patterns 512, the third alignment patterns 513, and the fourth alignment patterns 514 (refer to FIG. 3) of the first alignment key 500a and the second alignment key 500b. That is, the light blocking part 340a may have a size different from those of the first alignment key 500a and the second alignment key 500b and may have substantially the same shape as the first alignment key 500a and the second alignment key 500b.

In an embodiment, the sizes of the light blocking parts 340 and 340a may be ⅛ to ⅕ of the sizes of the first alignment key 500a and the second alignment key 500b. For example, the widths WD2 of the light blocking parts 340 and 340a when viewed in a plan view may be ⅛ to ⅕ of the widths WD1 of the first alignment key 500a and the second alignment key 500b.

TABLE 1

| | | | | | | (Width of | |
|---|---|---|---|---|---|---|---|
| | | | Width | | Whether | alignment | Whether |
| | Width | | (μm) of | | non-zero | pattern + | zero |
| | (μm) of | Separation | light | | order | Separation | order |
| | alignment | gap | blocking | Order | light is | gap)/Order | light is |
| | pattern | (μm) | part | light | blocked | light | blocked |
| 1 | 4 | 4 | 8 | 3 | ◯ | 2.67 | ◯ |
| 2 | 4 | 4 | 6 | 1 | X | 8 | ◯ |
| 3 | 3 | 3 | 6 | 3 | ◯ | 2 | ◯ |
| 4 | 3 | 3 | 6 | 1 | X | 6 | ◯ |
| 5 | 3 | 3 | 4 | 1 | X | 6 | X |
| 6 | 2 | 2 | 4 | 1 | X | 4 | X |

Table 1 shows simulation results representing whether zero order light is blocked depending on the width of the light blocking part. In the simulation, the widths WD1 of the first alignment key 500a and the second alignment key 500b were set to about 30 μm. In Table 1, “Width of alignment pattern” means the width of each individual pattern of the first alignment patterns 511, the second alignment patterns 512, the third alignment patterns 513, and the fourth alignment patterns 514, “Separation gap” means the separation gap between adjacent individual patterns of the first alignment patterns 511, the second alignment patterns 512, the third alignment patterns 513, or the fourth alignment patterns 514, “Order light” means order light other than zero order light among order lights that are reflected by the first alignment key 500a and the second alignment key 500b and incident to the objective lens 320, and “(Width of alignment pattern+Separation gap)/Order light” is a value obtained by dividing the sum of the width of the alignment pattern and the separation gap by the order light and means a light transmittance for each order light. “O” means blocked, “X” means unblocked.

Referring to Table 1, the type of order light capable of being incident to the objective lens 320 may vary depending on the width of the alignment pattern, the separation gap, and/or the width of the light blocking part. Referring to the third row and the fourth row of Table 1, it was confirmed that when the width of the alignment pattern was set to 3 μm, the separation gap was set to 3 μm, and/or the width of the light blocking part was set to 6 μm, not only zero order light but also first order light and third order light were capable of being incident to the objective lens 320, and the zero order light and the third order light were blocked. Furthermore, referring to the fifth row of Table 1, it was confirmed that when the width of the alignment pattern was set to 3 μm, the separation gap was set to 3 μm, and/or the width of the light blocking part was set to 4 μm, zero order light and first order light were capable of being incident to the objective lens 320, and neither the zero order light nor the first order light was blocked. In addition, referring to the sixth row of Table 1, it was confirmed that when the width of the alignment pattern was set to 2 μm, the separation gap was set to 2 μm, and/or the width of the light blocking part was set to 4 μm, zero order light and first order light were capable of being incident to the objective lens 320, and neither the first order light nor the zero order light was blocked. Accordingly, it can be seen that zero order light is completely blocked when the first alignment key 500a and the second alignment key 500b have a width of about 30 μm and the light blocking part 340 has a width of about 6 μm or more. That is, zero order light may be completely blocked when the size of the light blocking part is about ⅕ of the sizes of the first alignment key and the second alignment key.

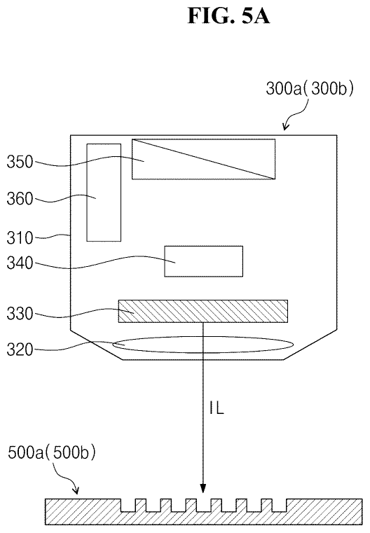

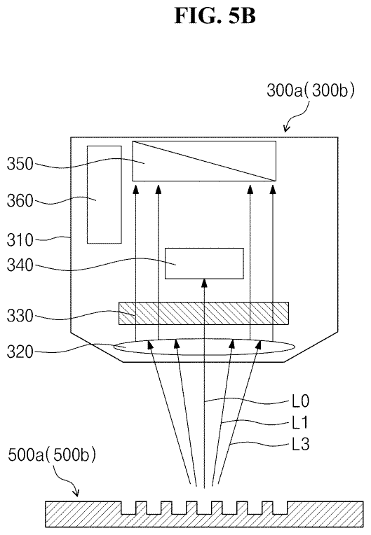

FIGS. 5A and 5B are sectional views illustrating a process in which light emitted from the first image device or the second imaging device is reflected by the first alignment key or the second alignment key and blocked by the light blocking part in the semiconductor manufacturing apparatus according to an embodiment of the present disclosure.

Referring to FIG. 5A, irradiation light IL may be emitted from the light source 330 of the first imaging device 300a or the second imaging device 300b. The irradiation light IL may be white light or red light. The light blocking part 340 may be located over the light source 330 (e.g., behind the light source 330 with respect to the direction of light emission). Accordingly, the irradiation light IL may not be blocked by the light blocking part 340. The irradiation light IL emitted from the light source 330 may transmit through the objective lens 320 and may be applied to the first alignment key 500a or the second alignment key 500b.

Referring to FIG. 5B, the irradiation light IL may be reflected by the first alignment key 500a or the second alignment key 500b, and a diffraction or interference phenomenon may appear. Accordingly, reflected light may be formed. The reflected light may include a plurality of order lights formed by the diffraction and/or interference. In other words, the reflected light reflected from the first alignment key 500a or the second alignment key 500b may include portions having different intensities. The plurality of order lights may be diffracted and/or interfered in various directions depending on the angle at which the light is incident and the shape of the first alignment key 500a or the second alignment key 500b, and the order may vary depending on the angle at which the light is reflected. In this case, constructive interference and destructive interference may occur, and light having the highest intensity that vertically travels straight due to the constructive interference may be zero order light L0. Among lights reflected at angles different from the incident angle due to the constructive interference, light having the second highest intensity may be first order light L1, and light having the next highest intensity after the first order light L1 may be third order light L3. That is, the plurality of order lights formed due to the constructive interference may include the zero order light and the (2n−1) order lights (here, n being a non-zero integer).

Next, the reflected light reflected from the first alignment key 500a or the second alignment key 500b may travel through the objective lens 320 of the first imaging device 300a or the second imaging device 300b. The objective lens 320 may change the travel direction of the reflected light through refraction, and accordingly, the reflected light may vertically travel straight in the first imaging device 300a or the second imaging device 300b.

In an embodiment, the light blocking part 340 may block one portion of the reflected light reflected from the first alignment key 500a or the second alignment key 500b. Here, the one portion of the reflected light may include one or some of the plurality of order lights. More specifically, the light blocking part 340 may block a portion having the highest intensity among the portions of the reflected light having different intensities. The light blocking part 340 may block, for example, the zero order light L0 among the plurality of order lights.

In an embodiment, another portion of the reflected light that is not blocked by the light blocking part 340 may be provided to the photo detector 360 through the light guide 350. In other words, among the portions of the reflected light having different intensities, at least one other portion other than the portion having the highest intensity may be provided to the photo detector 360. More specifically, among the plurality of order lights transmitting through the objective lens 320, other order lights other than the zero order light L0 blocked by the light blocking part 340 may be provided to the photo detector 360 through the light guide 350.

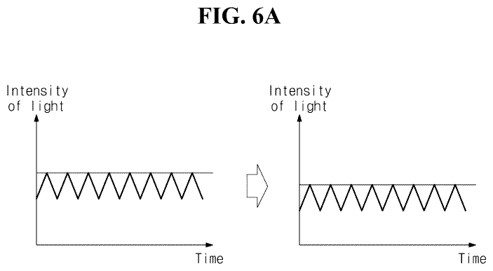

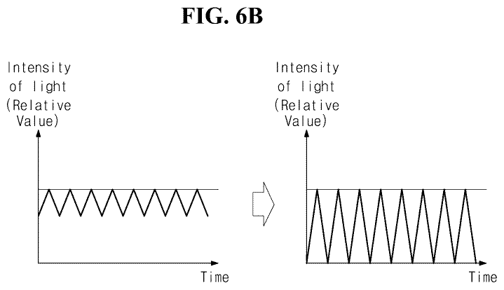

FIGS. 6A and 6B are signal graphs recognized by the photo detector included in the semiconductor manufacturing apparatus according to an embodiment of the present disclosure. More specifically, FIG. 6A is a graph depicting the intensity of light recognized by the photo detector over time. The left graph represents the case in which the light blocking part does not exist, and the right graph represents the case in which the light blocking part exists. Here, the x-axis represents time, and the y-axis represents the intensity of light. FIG. 6B is a graph depicting a digital signal obtained by converting a light signal recognized by the photo detector. The left graph represents the case in which the light blocking part does not exist, and the right graph represents the case in which the light blocking part exists. Here, the x-axis represents time, and the y-axis represents a relative value when the maximum value of the light signal is set to 1.

Referring to FIG. 6A, when the light blocking part 340 does not exist, the zero order light L0 (refer to FIG. 5B) may pass as it is without being blocked. In this case, the zero order light L0 having the largest amplitude may overpower the photo detector 360, and therefore the overall light signal may exhibit a flat pattern on the graph. Meanwhile, when the light blocking part 340 exists, the zero order light L0 may be blocked. In this case, only the high order lights, such as the first order light L1 (refer to FIG. 5B) and the third order light L3 (refer to FIG. 5B), may be recognized by the photo detector, and therefore the amplitude of the light signal may be increased. That is, the amplitude of the oscillation pattern of local maximum values and local minimum values over time on the graph may increase. As a result, the contrast of an optical analog signal illustrated as the intensity of light may be increased.

Referring to FIG. 6B, when the light blocking part 340 does not exist, the zero order light L0 is not blocked so that even after the digital conversion, due to the presence of the zero order light L0 (e.g., which may result in a noise phenomenon), the fluctuation of the light signal may not be large, and a tendency to maintain a low contrast may appear. Since the discrimination of the pattern increases as the contrast increases, the low contrast caused by the presence of the zero order light L0 may decrease the discrimination of the pattern. In contrast, when the light blocking part 340 exists, the zero order light L0 is blocked so that the contrast may further increase even after the digital signal conversion, and thus a detailed pattern may be more clearly identified. In other words, the alignment or pattern of the first alignment key 500a and the second alignment key 500b may be more finely sensed. Accordingly, the separation gaps LW of the first alignment patterns 511, the second alignment patterns 512, the third alignment patterns 513, and the fourth alignment patterns 514 that are recognizable by the first imaging device 300a and the second imaging device 300b may be decreased. For example, as illustrated in FIG. 3, the separation gaps LW of the first alignment patterns 511, the second alignment patterns 512, the third alignment patterns 513, and the fourth alignment patterns 514 of the first alignment key 500a and the second alignment key 500b may range from 0.3 μm to 0.7 μm. As the separation gaps LW of the first alignment patterns 511, the second alignment patterns 512, the third alignment patterns 513, and the fourth alignment patterns 514 decrease, an alignment error may decrease, and alignment accuracy may increase. Thus, the alignment accuracy may be improved by the light blocking part 340.

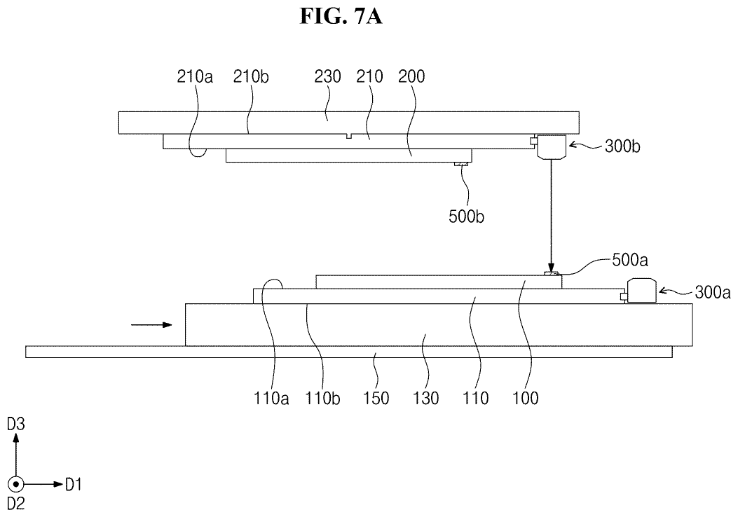

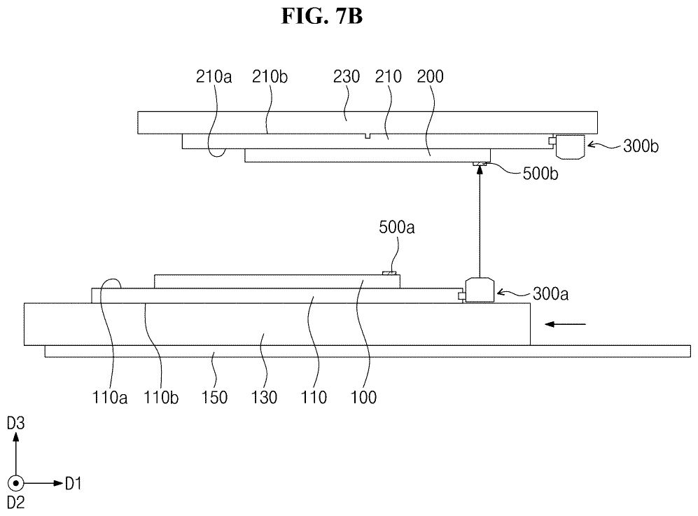

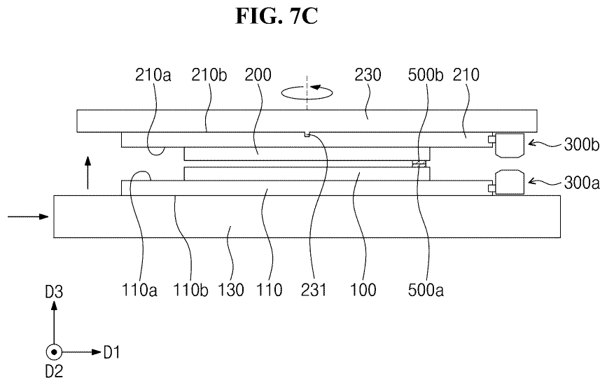

FIGS. 7A to 7C are sectional views illustrating an operating method of the semiconductor manufacturing apparatus according to an embodiment of the present disclosure.

Referring to FIG. 7A, the first substrate 100 and the second substrate 200 may be received on the first chuck 110 and the second chuck 210, respectively. The first substrate 100 may be provided on the first surface 110a of the first chuck 110, and the second substrate 200 may be provided on the third surface 210a of the second chuck 210. The first substrate 100 and the second substrate 200 may include the first alignment key 500a and the second alignment key 500b, respectively.

The first chuck 110 may be moved in the first direction D1 and the second direction D2 by the first stage 130. The first stage 130 may move the first chuck 110 using the rail 150 to allow the second imaging device 300b to face the first alignment key 500a of the first substrate 100.

The second imaging device 300b may take an image of the first alignment key 500a by applying the irradiation light IL (refer to FIG. 5A) in the direction opposite to the third direction D3 (e.g., in a downward direction as shown in FIG. 7A). One portion (e.g., a first portion) of reflected light reflected from the first alignment key 500a may be blocked by the light blocking part 340 (refer to FIG. 5B) provided in the second imaging device 300b, and another portion (e.g., a second portion) of the reflected light that is not blocked by the light blocking part 340 may be guided to the photo detector 360 (refer to FIG. 5B) by the light guide 350 (refer to FIG. 5B). The photo detector 360 may recognize (e.g., receive) the other portion of the reflected light guided by the light guide 350 as an optical analog signal and may convert the optical analog signal into a digital signal. The photo detector 360 may analyze the digital signal to obtain an alignment coordinate value for the first alignment key 500a.

Referring to FIG. 7B, the first stage 130 may move the first chuck 110 in the first direction D1 and the second direction D2 using the rail 150 to allow the first imaging device 300a to face the second alignment key 500b of the second substrate 200.

The first imaging device 300a may take an image of the second alignment key 500b by applying the irradiation light IL (refer to FIG. 5A) in the third direction D3. One portion (e.g., a first portion) of reflected light reflected from the second alignment key 500b may be blocked by the light blocking part 340 (refer to FIG. 5B) provided in the first imaging device 300a, and another portion (e.g., a second portion) of the reflected light that is not blocked by the light blocking part 340 may be guided to the photo detector 360 (refer to FIG. 5B) by the light guide 350 (refer to FIG. 5B). The photo detector 360 may recognize (e.g., receive) the other portion of the reflected light guided by the light guide 350 as an optical analog signal and may convert the optical analog signal into a digital signal. The photo detector 360 may analyze the digital signal to obtain an alignment coordinate value for the second alignment key 500b. Accordingly, the alignment coordinate values of the first alignment key 500a and the second alignment key 500b may all be obtained.

Referring to FIG. 7C, an alignment process may be performed on the first substrate 100 and the second substrate 200. More specifically, the alignment process may be a process of aligning the first substrate 100 and the second substrate 200 with each other by comparing the alignment coordinate values of the first alignment key 500a and the second alignment key 500b with the previously set alignment coordinate values. Using the alignment coordinate values, the first chuck 100 may be moved in the first direction D1, the second direction D2, and/or the third direction D3 by the first stage 130, and the second chuck 210 may rotate using the rotating part 231 of the second stage 230. The coordinates of the first alignment key 500a and the second alignment key 500b may be finally matched with the set coordinate values by the movement of the first chuck 110 and/or the rotation of the second chuck 210, and thus the alignment of the first substrate 100 and the second substrate 200 may be completed.

A substrate bonding process may be performed after the alignment process. The first chuck 110 may be moved in the third direction D3 by the first stage 130 in the state in which the first substrate 100 and the second substrate 200 are aligned with each other. Accordingly, the first substrate 100 and the second substrate 200 may be bonded to each other.

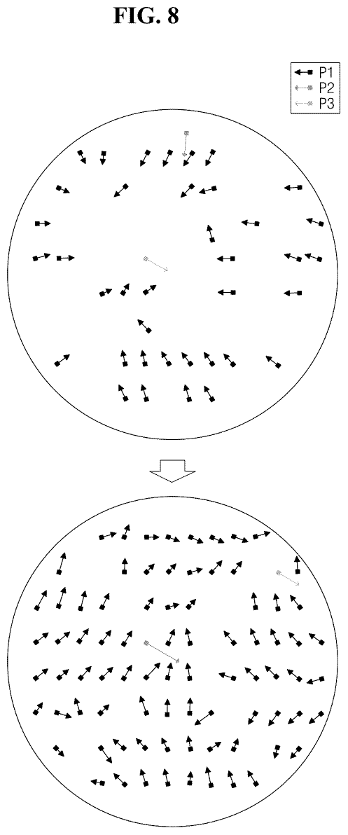

FIG. 8 is a view illustrating a simulation result obtained by measuring an alignment error when substrates are bonded using the semiconductor manufacturing apparatus according to an embodiment of the present disclosure. More specifically, the upper drawing illustrates a recognition result of the first alignment keys 500a (refer to FIG. 1) or the second alignment keys 500b (refer to FIG. 1) when the light blocking part 340 (refer to FIG. 5B) does not exist, and the lower drawing illustrates a recognition result of the first alignment keys 500a or the second alignment keys 500b when the light blocking part 340 exists. A plurality of arrows are illustrated in three stages depending on the degree of alignment error of the first alignment keys 500a or the second alignment keys 500b. P1 represents the case in which the alignment error is less than 0.1 μm, P2 represents the case in which the alignment error ranges from 0.1 μm to 0.5 μm, and P3 represents the case in which the alignment error ranges from 0.5 μm to 0.7 μm. The directions of the arrows indicate the directions in which the alignment errors occurred. The case in which the alignment error exceeds 0.7 μm is not illustrated.

Referring to FIG. 8, when the light blocking part 340 (refer to FIG. 1) does not exist, as illustrated in the upper drawing, the total number of P1, P2, and P3 is less than or equal to half of the total number of the first alignment keys 500a (refer to FIG. 1) or the second alignment keys 500b (refer to FIG. 1) included in the first substrate 100 (refer to FIG. 1) or the second substrate 200 (refer to FIG. 1), respectively. Meanwhile, when the light blocking part 340 exists, as illustrated in the lower drawing, the total number of P1, P2, and P3 is more than or equal to half of the total number of the first alignment keys 500a or the second alignment keys 500b included in the first substrate 100 or the second substrate 200, respectively, and the proportion of P1 with a small alignment error also increases. Accordingly, it can be confirmed that the alignment error of the first substrate 100 and the second substrate 200 decreases when the light blocking part 340 exists.

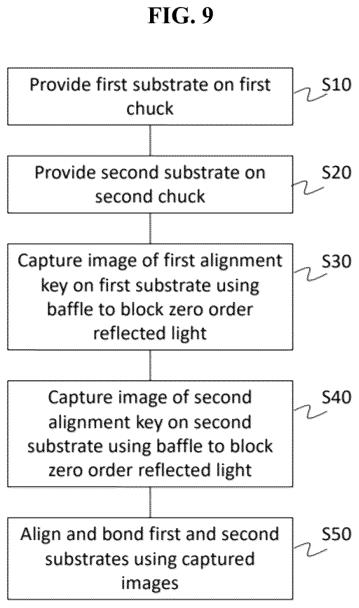

FIG. 9 shows a method of manufacturing a semiconductor device according to an embodiment.

Referring to FIG. 9, in step S10, a first substrate 100 is provided on a first chuck 110. The first substrate 100 may have a first alignment key 500a formed thereon. Then, in step S20, a second substrate 200 is provided on a second chuck 210. The second substrate 200 may have a second alignment key 500b formed thereon. The second chuck 210 may be positioned above the first chuck 110 such that the first substrate 100 and the second substrate 200 face each other.

In steps S30 and S40, a first imaging device 300a positioned next to the first chuck 110 may capture a first image of the second alignment key 500b and a second imaging device 300b positioned next to the second chuck 210 may capture a second image of the first alignment key 500a. The first imaging device 300a and the second imaging device 300b may each include a baffle 340 that blocks zero order light L0 reflected by the respective alignment keys such that only higher order reflected light (e.g., L1, L3) is received.

In step S50, the first substrate 100 and the second substrate 200 are aligned and bonded using the first image and the second image. For example, the controller described above may move the first stage 130 and the second stage 230 to align and bond the first substrate 100 and the second substrate 200.

According to the embodiments of the present disclosure, the semiconductor manufacturing apparatus and method of manufacturing the semiconductor device may increase the contrast of a light signal and may improve the alignment accuracy of substrates.

While the present disclosure has been described with reference to embodiments thereof, it will be apparent to those of ordinary skill in the art that various changes and modifications may be made thereto without departing from the spirit and scope of the present disclosure.

What is claimed is:

1. A semiconductor manufacturing apparatus comprising:
a first chuck having a first surface and a second surface opposite each other, the first chuck being configured to receive a first substrate on the first surface;
a second chuck having a third surface and a fourth surface opposite each other, the second chuck being configured to receive a second substrate on the third surface;
a first imaging device connected to one side of the first chuck; and
a second imaging device connected to one side of the second chuck,
wherein each of the first imaging device and the second imaging device includes a light blocking part, and
wherein, for each of the first imaging device and the second imaging device, the light blocking part is configured to block a first portion of reflected light reflected from a first alignment key on the first substrate or a second alignment key on the second substrate.

2. The semiconductor manufacturing apparatus of claim 1, wherein the reflected light includes a plurality of order lights formed by diffraction and/or interference, and the first portion of the reflected light includes one or some of the plurality of order lights.

3. The semiconductor manufacturing apparatus of claim 1, wherein each of the first imaging device and the second imaging device further includes:
a light source configured to emit light; and
a photo detector configured to detect a second portion of the reflected light,
wherein each of the first imaging device and the second imaging device has a first end, and for each of the first imaging device and the second imaging device, the light source is disposed between the first end and the light blocking part, and
wherein the first end of the first imaging device faces upward, and the first end of the second imaging device faces downward.

4. The semiconductor manufacturing apparatus of claim 3, wherein each of the first imaging device and the second imaging device further includes:
an objective lens configured to transmit the light emitted from the light source; and
a light guide configured to guide light not blocked by the light blocking part to the photo detector,
wherein the light source is provided between the objective lens and the light blocking part, and
wherein the light blocking part is provided between the light source and the light guide.

5. The semiconductor manufacturing apparatus of claim 3, wherein, for each of the first imaging device and the second imaging device, the light source is configured to emit white light and/or red light.

6. The semiconductor manufacturing apparatus of claim 3, further comprising:
a first stage provided on the second surface of the first chuck; and
a second stage provided on the fourth surface of the second chuck,
wherein the first chuck is movable by the first stage in a first direction parallel to the second surface of the first chuck, a second direction parallel to the second surface and crossing the first direction, and a third direction perpendicular to the first direction and the second direction, and
wherein the second chuck is rotatable about a rotational axis parallel to the third direction.

7. The semiconductor manufacturing apparatus of claim 6, wherein, for each of the first imaging device and the second imaging device, the photo detector is configured to convert recognized light signals into digital signals and obtain alignment coordinate values of the first substrate and the second substrate using the digital signals, and
wherein the first chuck is configured to move and/or the second chuck is configured to rotate to align the first substrate and the second substrate with each other using the obtained alignment coordinate values.

8. The semiconductor manufacturing apparatus of claim 1, wherein, for each of the first imaging device and the second imaging device, the light blocking part is configured to block the first portion of reflected light reflected from the first alignment key and the second alignment key, each of which includes first alignment patterns, second alignment patterns, third alignment patterns, and fourth alignment patterns,
wherein the first alignment patterns are arranged in a first direction parallel to the first surface of the first chuck, have bar shapes extending in a second direction parallel to the first surface and crossing the first direction, and constitute a first alignment pattern group,
wherein the second alignment patterns are arranged in the second direction, have bar shapes extending in the first direction, and constitute a second alignment pattern group,
wherein the third alignment patterns are arranged in the first direction, have bar shapes extending in the second direction, and constitute a third alignment pattern group,
wherein the fourth alignment patterns are arranged in the second direction, have bar shapes extending in the first direction, and constitute a fourth alignment pattern group, and
wherein the first alignment pattern group, the second alignment pattern group, the third alignment pattern group, and the fourth alignment pattern group are arranged in a clockwise direction to form a pinwheel shape in a plan view of the semiconductor manufacturing apparatus.

9. The semiconductor manufacturing apparatus of claim 8, wherein a first gap between adjacent first alignment patterns, a second gap between adjacent second alignment patterns, a third gap between adjacent third alignment patterns, or a fourth gap between adjacent fourth alignment patterns is in a range from 0.3 μm to 0.7 μm.

10. The semiconductor manufacturing apparatus of claim 1, wherein, when viewed in a plan view of the semiconductor manufacturing apparatus:
the light blocking part of the first imaging device is configured to block the first portion of reflected light reflected from the second alignment key having a larger area than the light blocking part of the first imaging device; or
the light blocking part of the second imaging device is configured to block the first portion of reflected light reflected from the first alignment key having a larger area than the light blocking part of the second imaging device.

11. The semiconductor manufacturing apparatus of claim 1, wherein, for each of the first imaging device and the second imaging device, the light blocking part has a square shape in a plan view of the semiconductor manufacturing apparatus, and
wherein a size of the light blocking part of the first imaging device or the light blocking part of the second imaging device is ⅛ to ⅕ of a size of the second alignment key or the first alignment key, respectively.

12. The semiconductor manufacturing apparatus of claim 1, wherein, for each of the first imaging device and the second imaging device, the light blocking part has a pinwheel shape in a plan view of the semiconductor manufacturing apparatus, and
wherein a size of the light blocking part of the first imaging device or the light blocking part of the second imaging device is ⅛ to ⅕ of a size of the second alignment key or the first alignment key, respectively.

13. The semiconductor manufacturing apparatus of claim 1, wherein, for each of the first imaging device and the second imaging device, the light blocking part is a spot mirror.

14. A semiconductor manufacturing apparatus comprising:
a first chuck having a first surface and a second surface opposite each other, the first chuck being configured to receive a first substrate on the first surface;
a second chuck having a third surface and a fourth surface opposite each other, the second chuck being configured to receive a second substrate on the third surface;
a first imaging device connected to one side of the first chuck; and
a second imaging device connected to one side of the second chuck,
wherein each of the first imaging device and the second imaging device includes a light blocking part,
wherein reflected light reflected from a first alignment key on the first substrate and a second alignment key on the second substrate includes a first portion having a first intensity and a second portion having a second intensity lower than the first intensity, and
wherein, for each of the first imaging device and the second imaging device, the light blocking part is configured to block the first portion of the reflected light.

15. The semiconductor manufacturing apparatus of claim 14, wherein each of the first imaging device and the second image device further includes:
a light source configured to emit light; and
a photo detector configured to detect the second portion of the reflected light,
wherein each of the first imaging device and the second imaging device has a first end, and for each of the first imaging device and the second imaging device, the light source is disposed between the first end and the light blocking part, and
wherein the first end of the first imaging device faces upward, and the first end of the second imaging device faces downward.

16. The semiconductor manufacturing apparatus of claim 15, wherein each of the first imaging device and the second image device further includes:
an objective lens configured to transmit the light emitted from the light source; and
a light guide configured to guide light not blocked by the light blocking part to the photo detector,
wherein the light source is provided between the objective lens and the light blocking part, and
wherein the light blocking part is provided between the light source and the light guide.

17. The semiconductor manufacturing apparatus of claim 14, further comprising:
a first stage provided on the second surface of the first chuck; and
a second stage provided on the fourth surface of the second chuck,
wherein the first chuck is movable by the first stage in a first direction parallel to the second surface of the first chuck, a second direction parallel to the second surface and crossing the first direction, and a third direction perpendicular to the first direction and the second direction, and
wherein the second chuck is rotatable about a rotational axis parallel to the third direction.

18. The semiconductor manufacturing apparatus of claim 14, wherein the first alignment key has substantially the same size and shape as the second alignment key, and
wherein the second imaging device is configured to capture an image of the first alignment key, and the first imaging device is configured to capture an image of the second alignment key.

19. The semiconductor manufacturing apparatus of claim 14, wherein the reflected light includes a plurality of order lights formed by diffraction and/or interference, and the first portion of the reflected light is zero order light among the plurality of order lights.

20. A semiconductor manufacturing apparatus comprising:
a first chuck having a first surface and a second surface opposite each other, the first chuck being configured to receive a first substrate on the first surface;
a second chuck having a third surface and a fourth surface opposite each other, the second chuck being configured to receive a second substrate on the third surface;
a first imaging device connected to one side of the first chuck; and
a second imaging device connected to one side of the second chuck,
wherein each of the first imaging device and the second imaging device includes:
a light source configured to emit light;
a light blocking part configured to block a first portion of reflected light reflected from a first alignment key on the first substrate or a second alignment key on the second substrate;
an objective lens configured to transmit the light emitted from the light source;
a photo detector configured to detect a second portion of the reflected light, and
a light guide configured to guide the second portion of the reflected light to the photo detector, and
wherein, for each of the first imaging device and the second imaging device:
the light source is provided between the objective lens and the light blocking part,
the light blocking part is provided between the light source and the light guide, and
the reflected light includes a plurality of order lights formed by diffraction and/or interference, and the first portion of the reflected light blocked by the light blocking part is zero order light among the plurality of order lights.
